(19) United States
(12) Patent Application Publication
(10) Pub. No.: US 2024/0028791 A1
(43) Pub. Date: Jan. 25, 2024

(54) METHOD FOR GENERATING SPACE, INFORMATION PROCESSOR, AND COMPUTER-READABLE RECORDING MEDIUM RECORDING A PROGRAM

(71) Applicant: Panasonic Intellectual Property Corporation of America, Torrance, CA (US)

(72) Inventors: Hiroko IZUMI, Kanagawa (JP); Keiichi SENDA, Kanagawa (JP); Noriaki HORII, Kyoto (JP)

(73) Assignee: Panasonic Intellectual Property Corporation of America, Torrance, CA (US)

(21) Appl. No.: 18/376,132

(22) Filed: Oct. 3, 2023

Related U.S. Application Data
(63) Continuation of application No. PCT/JP2022/002426, filed on Jan. 24, 2022.

(30) Foreign Application Priority Data
Apr. 6, 2021 (JP) 2021-064681

(51) Int. Cl. G06F 30/20; G06F 30/12; G06F 30/13

(52) U.S. Cl. CPC G06F 30/20; G06F 30/12; G06F 30/13

(57) ABSTRACT

An information processor is configured to: acquire room layout information on a building with multiple first spaces; acquire installation information on at least one of an apparatus and a facility that are installed in each first space of the multiple first spaces; set a use application for each of the first spaces based on the room layout information and the installation information; define at least one second space by grouping the multiple first spaces including at least one of integration of two or more first spaces and division of one first space based on the use application; and output a result of the grouping.

### TECHNICAL FIELD

The present disclosure relates to a method for generating a space, an information processor, and a computer-readable recording medium recording a program.

### BACKGROUND ART

Patent Literature 1 below discloses a technique of proposing a housing space based on information indicating a user's preference.

However, depending on a lifestyle of a resident, multiple spaces such as a dining room and a kitchen may be used as one use application such as a dining kitchen, for example. In that case, managing multiple spaces provided in a house collectively in units of use application is more convenient for the resident than managing them individually in units of space.

### CITATION LIST

### Patent Literature

Patent Literature 1: WO 2018/139293 A

### SUMMARY OF INVENTION

It is an object of the present disclosure to acquire a method for generating a space, an information processor, and a computer-readable recording medium recording a program, enabling optimum space management to be achieved in accordance with a use application.

### Means for Solving the Problem

A method for generating a space according to an aspect of the present disclosure includes: by an information processor, acquiring room layout information on a building with multiple first spaces; acquiring installation information on at least one of an apparatus and a facility that are installed in each first space of the multiple first spaces; setting a use application for each of the first spaces based on the room layout information and the installation information; defining at least one second space by grouping the multiple first spaces including at least one of integration of two or more first spaces and division of one first space based on the use application; and outputting a result of the grouping.

### BRIEF DESCRIPTION OF DRAWINGS

FIG. 1 is a diagram illustrating a general configuration of a home control system according to an embodiment of the present disclosure.

FIG. 2 is a diagram illustrating an example of a control target of an apparatus.

FIG. 3 is a diagram illustrating a first example of a system configuration.

FIG. 4 is a diagram illustrating a second example of a system configuration.

FIG. 5 is a flowchart illustrating a flow of processing performed by a control unit.

FIG. 6 is a diagram illustrating an example of room layout information in a simplified manner.

FIG. 7 is a diagram illustrating an example of room layout information in a simplified manner.

FIG. 8 is a diagram illustrating an example of association information in a simplified manner.

FIG. 9 is a diagram illustrating an example of an application setting rule in a simplified manner.

FIG. 10 is a diagram illustrating an example of a space generation rule in a simplified manner.

FIG. 11 is a diagram illustrating an example of space information in a simplified manner.

FIG. 12 is a flowchart illustrating adjustment processing performed by a space generator.

FIG. 13 is a diagram illustrating an example of space information in a simplified manner.

FIG. 14 is a diagram corresponding to FIG. 3 and illustrating a system configuration according to a modification.

FIG. 15 is a diagram corresponding to FIG. 4 and illustrating a system configuration according to a modification.

FIG. 16 is a flowchart corresponding FIG. 5 and illustrating a flow of processing performed by a control unit.

FIG. 17 is a diagram illustrating an example of an operation screen displayed on a display.

FIG. 18 is a diagram illustrating an example of an inquiry screen to a user in a simplified manner.

### DESCRIPTION OF EMBODIMENTS

(Knowledge Underlying Present Disclosure)

In a facility such as a house including multiple spaces, space generation by integrating two or more spaces or dividing one space for optimum space management greatly affects convenience of the facility.

Unfortunately, conventional space generation is often left to user's own sensitivity, and thus causes complicated work for the user, and may rather deteriorate the convenience of the facility due to inappropriate division of the space.

To solve the problem as described above, the present inventors have found that optimum space management can be achieved by setting a use application of each of spaces based on an apparatus and a facility installed in the corresponding one of the spaces to automatically generate a space based on the use application, and have conceived the present disclosure.

Next, each aspect of the present disclosure will be described.

A method for generating a space according to an aspect of the present disclosure includes: by an information processor, acquiring room layout information on a building with multiple first spaces; acquiring installation information on at least one of an apparatus and a facility that arc installed in each first space of the multiple first spaces; setting a use application for each of the first spaces based on the room layout information and the installation information; defining at least one second space by grouping the multiple first spaces including at least one of integration of two or more first spaces and division of one first space based on the use application; and outputting a result of the grouping.

The present aspect enables optimum space management to be achieved in accordance with a use application by setting a use application of each first space based on the room layout information and the installation information to define the second space by grouping multiple first spaces based on the use application.

In the above aspect, the method further includes: by the information processor, acquiring user information associating the respective first spaces with corresponding users, and setting the use application based on the room layout information, the installation information, and the user information.

The present aspect enables improvement in accuracy in grouping of the multiple first spaces to achieve more optimum space management by setting the use application based on the room layout information, the installation information, and the user information.

In the above aspect, the method further includes: by the information processor, generating relationship information indicating a correspondence relationship between the second space and at least one of the apparatus and the facility installed in the second space, and outputting the relationship information to a control device that controls the apparatus and the facility via a communication network.

The present aspect enables improvement in convenience of the user because the user can control the apparatus and the facility in units of the second space with the control device.

In the above aspect, the method further includes: by the information processor, performing the grouping in accordance with a type of the use application of each of the first spaces.

The present aspect enables improvement in accuracy of the grouping to achieve more optimum space management by performing the grouping in accordance with the type of use application of each of the first spaces with the information processor.

In the above aspect, the method further includes: by the information processor, setting a type of the use application of each of the first spaces based on setting information in which a type of use application of each of the apparatus and the facility is set.

The present aspect enables improvement in accuracy of the grouping to achieve more optimum space management by setting the type of use application of each of the first spaces based on the setting information with the information processor.

In the above aspect, the at least one second space includes multiple second spaces, and the method further includes, by the information processor, performing adjustment for further dividing the second space when a total number of control targets of the apparatus and the facility and installed in each second space of the multiple second spaces is equal to or larger than a first threshold as a result of the grouping.

The present aspect enables avoiding a situation in which an enormous number of apparatuses and facilities are simultaneously displayed on a display screen of a control device to cause deterioration in visibility by further dividing the second space when the total number of the control targets of the apparatus and the facility is equal to or larger than the first threshold value.

In the above aspect, the at least one second space includes multiple second spaces, and the method further includes, by the information processor, performing adjustment for integrating two or more second spaces when a total number of the multiple second spaces is equal to or larger than a second threshold as a result of the grouping.

The present aspect enables avoiding a situation in which the second spaces enormously increase in number to cause deterioration in operability of the control device by integrating two or more second spaces when the total number of the multiple second spaces is equal to or larger than the second threshold value.

An information processor according to an aspect of the present disclosure includes: an acquisition unit that acquires room layout information on a building with multiple first spaces and installation information on at least one of an apparatus and a facility that are installed in each first space of the multiple first spaces; an application setting unit that sets a use application for each of the first spaces based on the room layout information and the installation information that are acquired by the acquisition unit; a space generator that defines at least one second space by grouping the multiple first spaces including at least one of integration of two or more first spaces and division of one first space based on the use application set by the application setting unit; and an output unit that outputs a result of the grouping performed by the space generator.

The present aspect enables optimum space management to be achieved in accordance with a use application by setting a use application of each first space based on the room layout information and the installation information to define the second space by grouping multiple first spaces based on the use application.

A computer-readable recording medium recording a program according to an aspect of the present disclosure causes an information processor to function as: an acquisition means that acquires room layout information on a building with multiple first spaces and installation information on at least one of an apparatus and a facility that are installed in each first space of the multiple first spaces; an application setting means that sets a use application for each of the first spaces based on the room layout information and the installation information that are acquired by the acquisition means; a space generation means that defines at least one second space by grouping the multiple first spaces including at least one of integration of two or more first spaces and division of one first space based on the use application set by the application setting means; and an output means that outputs a result of the grouping performed by the space generation means.

The present aspect enables optimum space management to be achieved in accordance with a use application by setting a use application of each first space based on the room layout information and the installation information to define the second space by grouping multiple first spaces based on the use application.

The present disclosure may also be implemented as a program for causing a computer to perform each characteristic function included in a method or a device as described above, or a system that operates with the program. It is needless to say that such a computer program can be distributed using a computer-readable non-transitory recording medium such as a CD-ROM, or via a communication network such as the Internet.

### Embodiments of Present Disclosure

Hereinafter, embodiments of the present disclosure will be described in detail with reference to the drawings. Elements denoted by the same reference numerals in different drawings represent the same or corresponding elements. The following embodiments show components, placement positions of the components, connection forms, the order of operations, and the like that are merely examples, and are not intended to limit the present disclosure. The present disclosure is limited only by the scope of claims. Thus, although the components in the following embodiments include a component that is not described in an independent claim indicating the most generic concept of the present disclosure and that is not necessarily required to achieve the object of the present disclosure, the component is described as constituting a more preferable form.

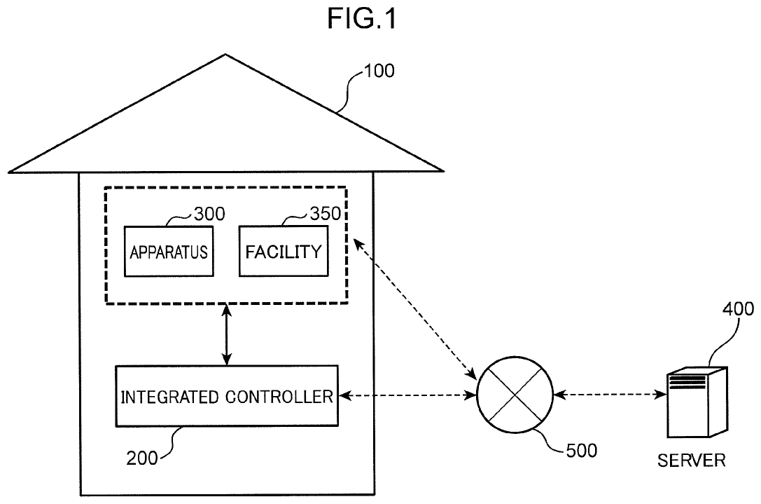

FIG. 1 is a diagram illustrating a general configuration of a home control system according to an embodiment of the present disclosure. The home control system includes a smart home 100, a communication network 500, and a server 400. Although FIG. 1 illustrates only one smart home 100 for simplification of description, multiple smart homes may be provided. The present disclosure is applied to a house such as the smart home 100, but is not limited thereto and may be applied to an indoor facility such as an office, a restaurant, or a commercial facility. The present disclosure is not limited to the indoor facility, and may be applied to a space including both an indoor space and an outdoor space.

The smart home 100 includes multiple spaces (room, bathroom, toilet, entrance, corridor, and the like) in which multiple apparatuses 300 and multiple facilities 350 are installed. The apparatuses 300 include an electronic appliance such as a home appliance. The facilities 350 include an instrument, furniture, or the like that is used in a fixed place. The smart home 100 is also provided with an integrated controller 200 for controlling operation of control targets of an apparatus 300 and a facility 350 included in the multiple apparatuses 300 and the multiple facilities 350. The integrated controller 200 can mutually perform data communication with the control targets of the apparatus 300 and the facility 350 via an appropriate communication network such as a wireless LAN or a public network.

The server 400 is a cloud server, an edge server, or the like, and manages the entire home control system. The communication network 500 is an appropriate communication network such as a public network. The communication network 500 is connected to the server 400, the integrated controller 200, the apparatus 300, and the facility 350. With this configuration, the server 400 can perform data communication with the integrated controller 200, the apparatus 300, and the facility 350 via the communication network 500.

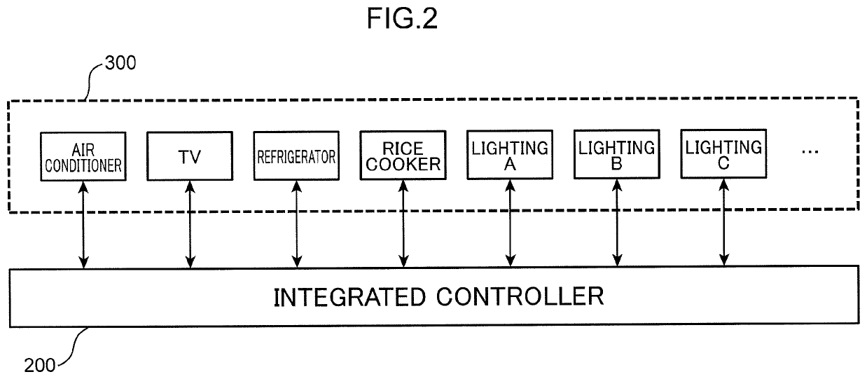

FIG. 2 is a diagram illustrating an example of a control target of the apparatus 300. As illustrated in this example, the control target of the apparatus 300 is any IoT apparatus such as an air conditioner, a TV, a refrigerator, a rice cooker, and lighting. Each apparatus 300 is connected to the integrated controller 200 as a control device via a communication network.

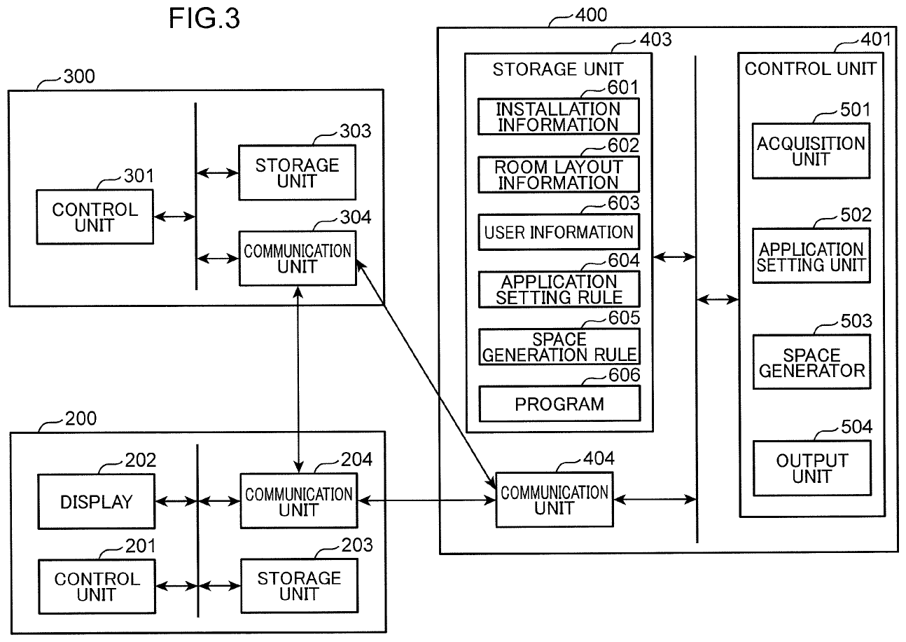

FIG. 3 is a diagram illustrating a first example of a system configuration. The home control system includes the integrated controller 200, the apparatus 300 (and the facility 350 that is not illustrated), and the server 400.

The apparatus 300 includes a control unit 301, a storage unit 303, and a communication unit 304. The control unit 301 is implemented as a function of a CPU or the like by executing a predetermined program. The storage unit 303 includes a flash memory and the like. The communication unit 304 includes a communication module corresponding to an appropriate communication method such as IP.

The integrated controller 200 includes a control unit 201, a display 202, a storage unit 203, and a communication unit 204. The control unit 201 is implemented as a function of a CPU or the like by executing a predetermined program. The display 202 is a touch panel display using liquid crystal, organic EL, or the like. The storage unit 203 includes an HDD, an SSD, a flash memory, or the like. The communication unit 204 includes a communication module corresponding to an appropriate communication method such as IP. The integrated controller 200 may be a smartphone or the like in which a predetermined application program is installed.

The server 400 includes a control unit 401, a storage unit 403, and a communication unit 404. The storage unit 403 includes an HDD, an SSD, a flash memory, or the like. The storage unit 403 stores installation information 601, room layout information 602, user information 603, an application setting rule 604, a space generation rule 605, and a program 606. The control unit 401 includes an acquisition unit 501, an application setting unit 502, a space generator 503, and an output unit 504 as functions implemented by an information processor such as a CPU executing a program 606 read out from the storage unit 403 to a ROM, a RAM, or the like. Details of these functions will be described later. The communication unit 404 includes a communication module corresponding to an appropriate communication method such as IP.

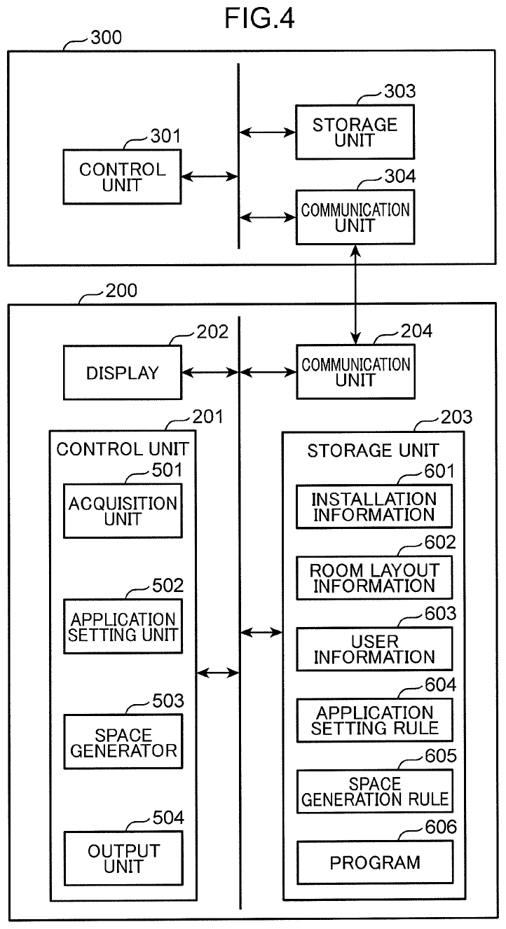

FIG. 4 is a diagram illustrating a second example of the system configuration. The home control system includes the integrated controller 200 and the apparatus 300 (and the facility 350 that is not illustrated), the integrated controller 200 being equipped with the function of the server 400 illustrated in FIG. 3.

The integrated controller 200 includes a control unit 201, a display 202, a storage unit 203, and a communication unit 204. The storage unit 203 stores the installation information 601, the room layout information 602, the user information 603, the application setting rule 604, the space generation rule 605, and the program 606. The control unit 201 includes the acquisition unit 501, the application setting unit 502, the space generator 503, and the output unit 504 as functions implemented by an information processor such as a CPU executing the program 606 read out from the storage unit 203 to a ROM, a RAM, or the like.

Hereinafter, the home control system using the system configuration illustrated in FIG. 3 will be described.

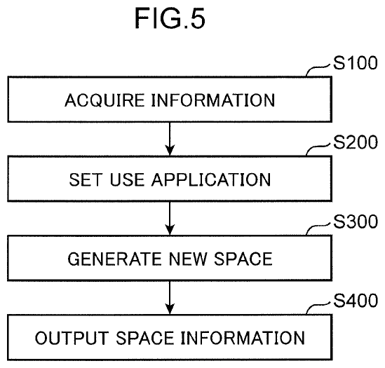

FIG. 5 is a flowchart illustrating a flow of processing performed by the control unit 401 of the server 400. The control unit 401 performs processing below for introduction of a system and for change of the apparatus 300 or the facility 350, such as addition, removal, and replacement thereof, thereby generating space information described later.

In step S100, the acquisition unit 501 first reads out the installation information 601, the room layout information 602, and the user information 603 from the storage unit 403 to acquire these pieces of information.

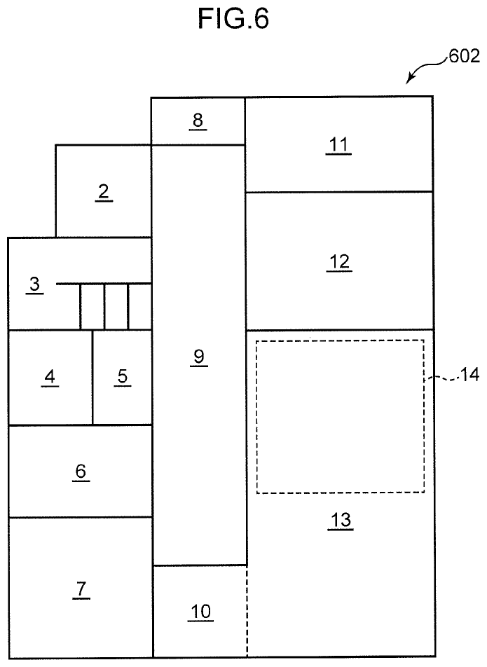

FIG. 6 is a diagram illustrating an example of the room layout information 602 in a simplified manner. The room layout information 602 is a CAD drawing for construction of the target smart home 100, and is stored in the storage unit 403 in advance, for example. The room layout information 602 is created by an operator of a management company or the like when the system is introduced into the smart home 100. Alternatively, the information may be created by a user (resident) of the smart home 100 instead of the operator, or may be created later instead of when the system is introduced. The CAD drawing may be a two-dimensional CAD drawing or a three-dimensional CAD drawing. The room layout information 602 includes multiple first spaces. FIG. 6 illustrates the example in which the first spaces include an entrance 2, a staircase 3, a bathroom 4, a washroom 5, a performance room 6, a theater room 7, a storage room 8, a corridor 9, a kitchen 11, a dining room 12, and a living room 13. The first spaces also include a tatami mat corner 10 connected to a part of the living room 13 without being separated by a wall. The living room 13 includes a partial region provided with a descending ceiling 14. The room layout information 602 includes coordinate data indicating positions of four corners or eight corners of each first space, or includes function data defining a boundary line or a boundary surface that is a boundary between adjacent first spaces.

The control unit 401 creates the room layout information 700 by defining multiple first spaces based on the room layout information 602 using a known technique of recognizing a space from a CAD drawing and assigning a space ID as identification information to each first space.

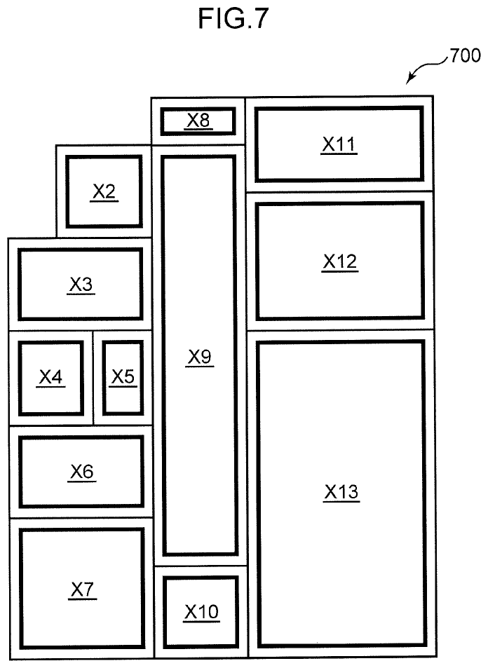

FIG. 7 is a diagram illustrating an example of the room layout information 700 in a simplified manner. The room layout information 700 indicates the entrance 2, the staircase 3, the bathroom 4, the washroom 5, the performance room 6, the theater room 7, the storage room 8, the corridor 9, the tatami mat corner 10, the kitchen 11, the dining room 12, and the living room 13 that are defined as first spaces X2 to X13, respectively. Each first space in the following description has the space ID assigned that is identical to its reference numeral.

As with the room layout information 602, the installation information 601 and the user information 603 are also created by the operator or the user when the system is introduced or later and stored in the storage unit 403 in advance.

The installation information 601 indicates the apparatuses 300 and the facilities 350 installed in the respective first spaces of the smart home 100. For example, the operator or the user displays an initial setting screen including the room layout information 700 and icons of representative apparatuses and facilities on the display 202 of the integrated controller 200, and drags and drops the icons of the apparatuses or the facilities into the first spaces in which the corresponding apparatuses or facilities are installed. This operation causes the apparatuses 300 and the facilities 350 to be associated with the corresponding first spaces in the room layout information 700 to create the installation information 601, and the installation information is transmitted to the server 400. Alternatively, the initial setting screen including a name of each first space in the room layout information 700 and a text input field for each first space may be displayed on the display 202 of the integrated controller 200 instead of a method of dragging and dropping the icons. In this case, the operator or the user describes names, types, or the like of the apparatuses 300 and the facilities 350 installed in the corresponding first spaces in the room layout information 700 in corresponding input fields in a text format. The control unit 201 receives input by the operator or the user to create the installation information 601, and transmits the information to the server 400. When the room layout information 602 already includes the installation information 601 of the apparatuses 300 and the facilities 350, the installation information 601 is not required to be created separately from the room layout information 602, 700.

The user information 603 indicates a user who mainly uses each first space of the smart home 100. For example, the operator or the user displays an initial setting screen including the room layout information 700 and icons of representative users (father, mother, first child, second child, and the like) on the display 202 of the integrated controller 200, and drags and drops the icons of the users to the first spaces mainly used by the corresponding users. This operation causes the users to be associated with the corresponding first spaces of the room layout information 700 to create the user information 603, and the user information is transmitted to the server 400. As with the installation information 601 described above, the user information 603 may be created by a method of description in a text format in an input field instead of a method of dragging and dropping the icons. When the smart home 100 has a single resident, the user information 603 is not required to be input and created. In contrast, when the smart home 100 has multiple residents such as family members, and multiple first spaces for respective different users with the same use application need to be distinguished (e.g., when bedrooms for respective persons are distinguished), the user information 603 is absolutely required to be input and created.

The control unit 401 creates association information 800 based on the installation information 601, the room layout information 602, and the user information 603, in which these pieces of information are associated with each other.

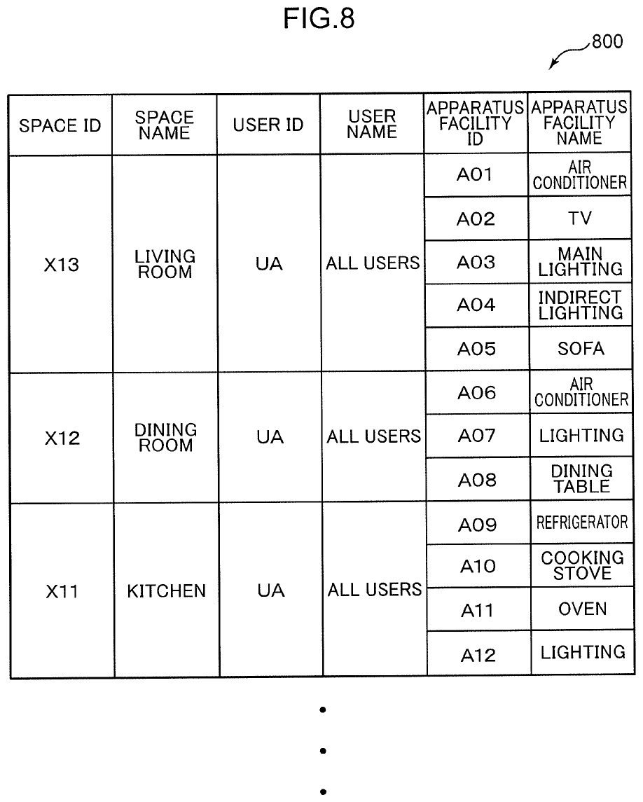

FIG. 8 is a diagram illustrating an example of the association information 800 in a simplified manner. The association information 800 includes a correspondence relationship among identification information (a space ID and a space name) on each of the first spaces of the smart home 100, identification information (a user ID and a user name) on a user who mainly uses each of the first spaces, and identification information (an apparatus facility ID and an apparatus facility name) on the apparatus 300 and the facility 350 installed in each of the first spaces.

FIG. 8 illustrates the example in which the living room (space ID: X13) is associated with all users (user ID: UA) representing all residents of the smart home 100, and an air conditioner (apparatus facility ID: A01), a television (apparatus facility ID: A02), a main lighting (apparatus facility ID: A03), an indirect lighting (apparatus facility ID: A04), and a sofa (apparatus facility ID: A05) are installed in the living room. The dining room (space ID: X12) is associated with all the users (user ID: UA), and an air conditioner (apparatus facility ID: A06), lighting (apparatus facility ID: A07), and a dining table (apparatus facility ID: A08) are installed in the dining room. The kitchen (space ID: X11) is associated with all the users (user ID: UA), and a refrigerator (apparatus facility ID: A09), a stove (apparatus facility ID: A10), an oven (apparatus facility ID: A11), and lighting (apparatus facility ID: A12) are installed in the kitchen.

With reference to FIG. 5, in subsequent step S200, the application setting unit 502 sets a use application of each first space in the room layout information 700 based on the association information 800 and the application setting rule 604.

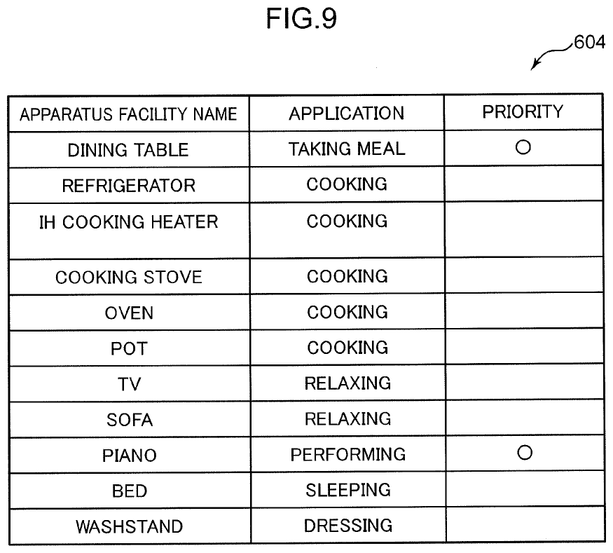

FIG. 9 is a diagram illustrating an example of the application setting rule 604 in a simplified manner. The application setting rule 604 defines a correspondence relationship between apparatus facility names of the apparatus 300 and the facility 350, and a type of use application indicating behavior of a user. For example, a use application of “taking meal” is defined for a dining table. For a refrigerator, an IH cooking heater, a cooking stove, an oven, and a pot, a use application of “cooking” is defined. For a television and a sofa, a use application of “relaxing” is defined. For a piano, a bed, and a washroom, use applications of “performing”, “sleeping”, and “dressing” are defined, respectively. Additionally, prior items are set for the apparatus 300 and the facility 350 having a use application with high expertise and exclusive use, the prior items being to be preferentially considered in setting of the use application. FIG. 9 illustrates the example in which prior items are set for the dining table specialized for the use application of “taking meal” and the piano specialized for the use application of “performing”. Additionally, the apparatuses 300 and the facilities 350 (air conditioner, lighting, and the like) having a use application with extremely low expertise and exclusive use are excluded from the application setting rule 604.

The application setting unit 502 sets a type of use application of each of the first spaces by specifying a type of use application of the apparatus 300 and the facility 350 installed in the corresponding one of the first spaces in the association information 800 from the application setting rule 604. FIGS. 8 and 9 show the examples in which each of the television and the sofa installed in the living room 13 has the use application of “relaxing”, so that the application setting unit 502 sets the use application of the first space X13 corresponding to the living room 13 to “relaxing”. The dining table installed in the dining room 12 has the use application of “taking meal”, so that the application setting unit 502 sets the use application of the first space X12 corresponding to the dining room 12 to “taking meal”. Each of the refrigerator, the stove, and the oven installed in the kitchen 11 has the use application of “cooking”, so that the application setting unit 502 sets the use application of the first space X11 corresponding to the kitchen 11 to “cooking”.

When multiple apparatuses 300 and facilities 350 having different use applications and being installed in one first space include an apparatus 300 or a facility 350 for which a prior item is set, the application setting unit 502 sets a use application to that of the apparatus 300 or the facility 350, and sets a use application by a majority rule when an apparatus 300 or a facility 350 for which a prior item is set is not included in the multiple apparatuses 300 and facilities 350. Alternatively, the application setting unit 502 may set the use application based on a majority rule. When an apparatus 300 or a facility 350 for which a prior item is installed, the application setting unit 502 may set the use application of the apparatus 300 or the facility 350 for the same number of votes in the majority rule, and set multiple use applications when an apparatus 300 or a facility 350 for which a prior item is set is not installed.

With reference to FIG. 5, in subsequent step S300, the space generator 503 generates a new space of a second space by grouping multiple first spaces based on the space generation rule 605. This grouping includes at least one of generating one second space by integrating two or more first spaces and generating two or more second spaces by dividing one first space.

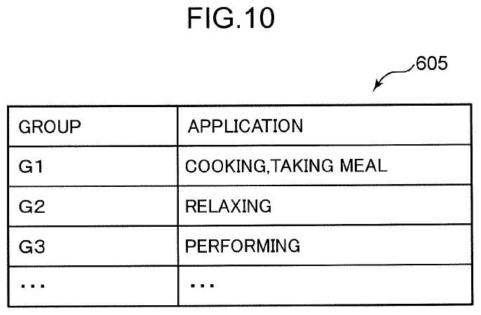

FIG. 10 is a diagram illustrating an example of the space generation rule 605 in a simplified manner. The space generation rule 605 defines a correspondence relationship between each group and one or more use applications such that similar use applications belong to the same group. FIG. 10 illustrates the example in which similar use applications such as “cooking” and “taking meal” are classified into a group G1, a use application such as “relaxing” is classified into a group G2, and a use application such as “performing” is classified into a group G3. Multiple space generation rules 605 to be applied for respective time zones may be prepared. Even for similar applications, applications related to human vision or hearing may be defined as different groups. For example, even for the same application of “viewing”, the performance room 6 (first space X6) in which viewing is performed audibly and the theater room 7 (first space X7) in which viewing is performed mainly visually may be defined as different groups.

The space generator 503 generates space information 701 including the second space generated by grouping the first spaces.

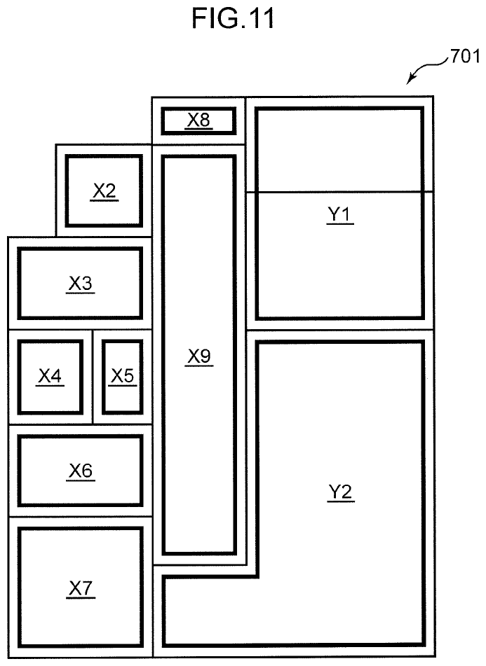

FIG. 11 is a diagram illustrating an example of the space information 701 in a simplified manner. FIG. 11 illustrates the example in which the use application of “cooking” of the kitchen 11 and the use application of “taking meal” of the dining room 12 are classified into the same group G1 to integrate the first space X11 corresponding to the kitchen 11 and the first space X12 corresponding to the dining room 12, thereby generating a second space Y1 (dining kitchen). Use applications of the living room 13 and the tatami mat corner 10 are common in “relaxing”, and are classified into the same group G2 to integrate the first space X13 corresponding to the living room 13 and the first space X10 corresponding to the tatami mat corner 10, thereby generating a second space Y2.

With reference to FIG. 5, in subsequent step S400, the output unit 504 outputs the space information 701 generated by the space generator 503. The space information 701 includes a result of generation of the second spaces Y1 and Y2 with the space generator 503. The output unit 504 may output the space information 701 as image information or character information. The character information is text information indicating that the kitchen 11 and the dining room 12 are integrated, for example. The control unit 201 of the integrated controller 200 can store the space information 701 received from the server 400 in the storage unit 203 and display the space information on the display 202.

### Effects of Embodiment

The present embodiment enables optimum space management to be achieved in accordance with a use application by setting the use application of each of the first spaces based on the room layout information 700 and the installation information 601 with the application setting unit 502 and grouping the multiple first spaces based on the use application with the space generator 503 to generate (define) the second space.

The present embodiment also enables improvement in accuracy of grouping the multiple first spaces with the space generator 503 to achieve more optimum space management by setting the use application of each of the first spaces based on the room layout information 700, the installation information 601, and the user information 603, with the application setting unit 502.

The present embodiment also enables improvement in accuracy of the grouping to achieve more optimum space management by performing the grouping in accordance with the type of use application of each of the first spaces with the space generator 503.

The present embodiment enables improvement in accuracy of grouping with the space generator 503 to achieve more optimum space management by setting a type of use application of each first space based on the application setting rule 604 (setting information) with the application setting unit 502.

(First Modification)

When a total number of control targets of the apparatuses 300 and the facilities 350 installed in each second space is equal to or larger than a first threshold as a result of the grouping of first spaces in step S300, the space generator 503 may perform adjustment for further dividing the second space.

When a total number of the second spaces is equal to or larger than a second threshold as a result of the grouping of first spaces in step S300, the space generator 503 may perform adjustment for integrating two or more second spaces.

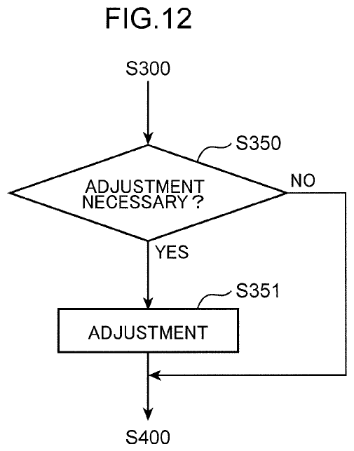

FIG. 12 is a flowchart illustrating adjustment processing performed by the space generator 503. In step S350 subsequent to step S300, the space generator 503 determines whether the grouping performed in step S300 needs to be adjusted. As described above, the space generator 503 determines that the grouping needs to be adjusted when the total number of control targets of the apparatuses 300 and the facilities 350 installed in each second space is equal to or larger than the first threshold (e.g., 10) as a result of the grouping in step S300. The space generator 503 also determines that the grouping needs to be adjusted when the total number of the second spaces is equal to or larger than the second threshold (e.g., 10) as a result of the grouping in step S300.

When the grouping does not need to be adjusted (step S350: NO), step S400 is performed.

When the grouping needs to be adjusted (step S350: YES), the space generator 503 performs adjustment processing of grouping in subsequent step S351.

When a total number of control targets of the apparatuses 300 and the facilities 350 installed in each second space is equal to or larger than the first threshold, the space generator 503 further divides the second space generated in step S300 to generate new space information 702.

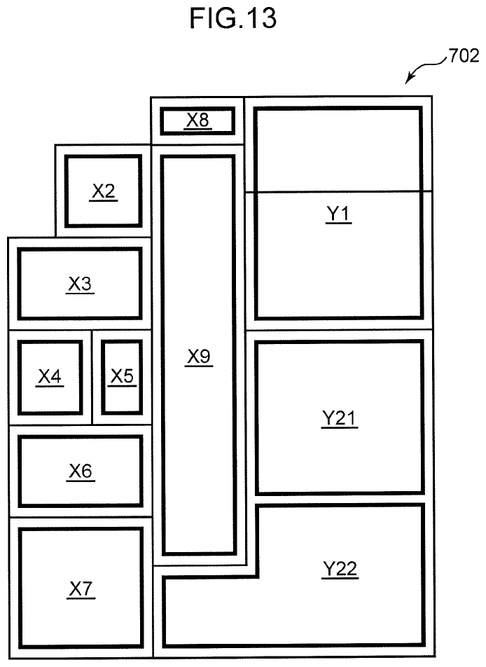

FIG. 13 is a diagram illustrating an example of the space information 702 in a simplified manner. The space information 702 includes the second space Y2 divided into two second spaces Y21 and Y22 because the total number of control targets of the apparatuses 300 and the facilities 350 installed in the second space Y2 is equal to or larger than the first threshold in the space information 701 illustrated in FIG. 11. In this example, the space generator 503 divides the second space Y2 into two regions that are a region (Y21) of the second space Y2 where the descending ceiling 14 is provided and the other region (Y22). With this configuration, a situation can be avoided in which an enormous number of apparatuses 300 and facilities 350 equal to or larger than the first threshold is simultaneously displayed on the display 202 and visibility is deteriorated.

When the total number of the second spaces is equal to or larger than the second threshold, the space generator 503 generates new space information 702 by performing adjustment for integrating the two or more second spaces generated in step S300.

For example, the space generator 503 reduces the total number of the second spaces by increasing an upper limit number of the apparatuses 300 and the facilities 350 that can be displayed in one display tab, when the total number of the second spaces (i.e., a total number of display tabs) is equal to or larger than the second threshold, in a form in which a control screen displayed on the display 202 includes multiple display tabs each of which displays the apparatuses 300 and the facilities 350 in one second space. With this configuration, a situation can be avoided in which the total number of the second spaces (the total number of display tabs) increases enormously to deteriorate operability of the integrated controller 200.

Examples of contents of another adjustment processing of grouping include the following.

When multiple spaces without being partitioned by walls are set as separate first spaces as a result of the grouping in step S300, the multiple first spaces may be integrated as one second space. Similarly, multiple first spaces partitioned by movable objects (bran, curtain, or the like) other than walls may be integrated as one second space. In this case, the room layout information 602 needs to include information indicating whether a wall exists between multiple first spaces and material information on a boundary between the multiple first spaces. Multiple first spaces to be integrated may be set by manual input with a user.

When the apparatus 300 and the facility 350 that are less likely to be installed in the same space are included in the same second space as a result of the grouping in step S300, the second space may be divided into multiple original first spaces. For example, when the piano and the refrigerator are included in the same second space, the grouping is probably wrong, and thus adjustment processing of returning the second space to the multiple original first spaces is performed. A list of the apparatuses 300 and the facilities 350 that are less likely to be installed in the same space is created in advance and stored in the storage unit 403.

When a three-dimensional CAD drawing can be prepared as the room layout information 602, one first space may be divided into multiple spaces by dividing the space into cuboids as much as possible. For example, when the descending ceiling 14 or a down floor is provided in a partial region of one first space, the first space can be divided into multiple spaces in the partial region and the other region.

(Second Modification)

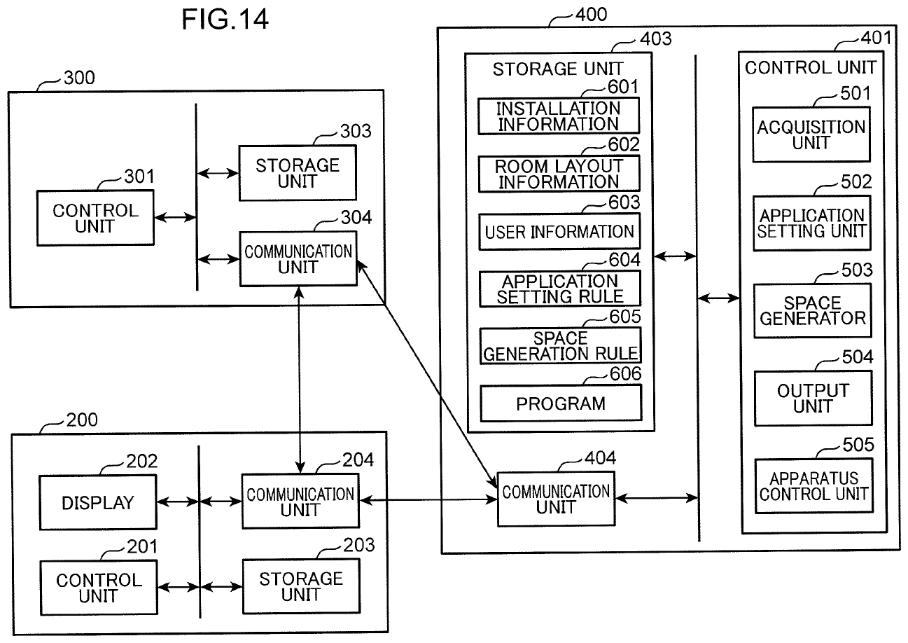

FIG. 14 is a diagram illustrating a system configuration according to the present modification corresponding to FIG. 3. The control unit 401 further includes an apparatus control unit 505.

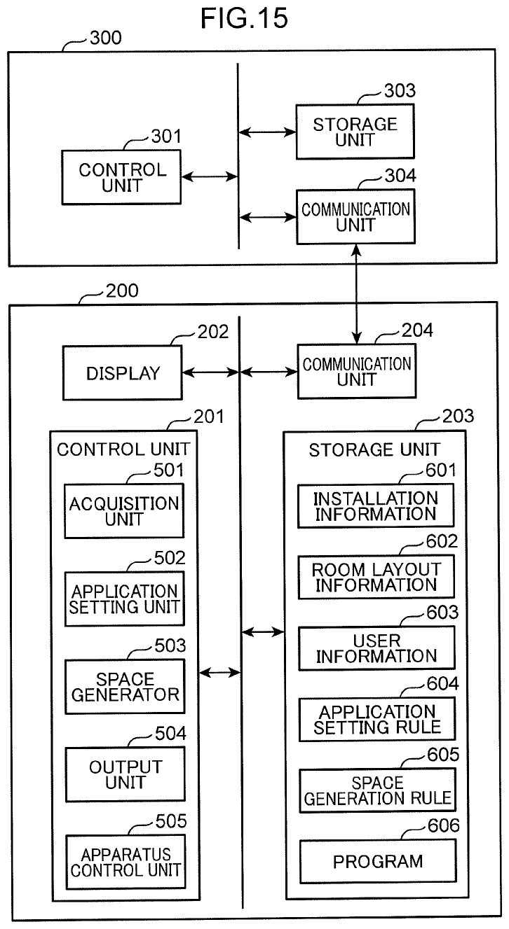

FIG. 15 is a diagram corresponding to FIG. 4 and illustrating a system configuration according to the present modification. The control unit 201 further includes the apparatus control unit 505.

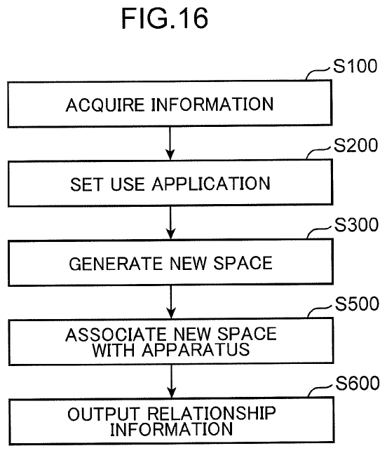

FIG. 16 is a flowchart corresponding FIG. 5 and illustrating a flow of processing performed by the control unit 401.

In step S500 subsequent to step S300, the apparatus control unit 505 assigns identification information (space ID and space name) to the second space generated in step S300. Then, the apparatus control unit 505 associates the identification information with the identification information on the apparatus 300 and the facility 350 installed in the second space to generate relationship information indicating a correspondence relationship therebetween. For example, when the dining room 12 and the kitchen 11 are integrated to generate a new second space, the apparatus control unit 505 assigns a new space ID and a new name (e.g., “dining kitchen”) to the second space. The apparatus control unit 505 associates the new space ID with apparatus facility IDs of control targets of the apparatuses 300 and the facilities 350 installed in the dining room 12 and the kitchen 11 to generate relationship information.

In subsequent step S600, the output unit 504 outputs the relationship information generated in step S500.

With reference to FIG. 14, the relationship information output by the output unit 504 is received by the communication unit 404. The communication unit 404 transmits the received relationship information to the integrated controller 200 via the communication network 500. The communication unit 204 of the integrated controller 200 receives the relationship information and inputs the received relationship information to the control unit 201. The control unit 201 creates display data based on the relationship information received. The control unit 201 inputs the created display data to the display 202. The display 202 displays an operation screen based on the display data received. Alternatively, an aspect of notification is not limited to display, and may be voice output or the like.

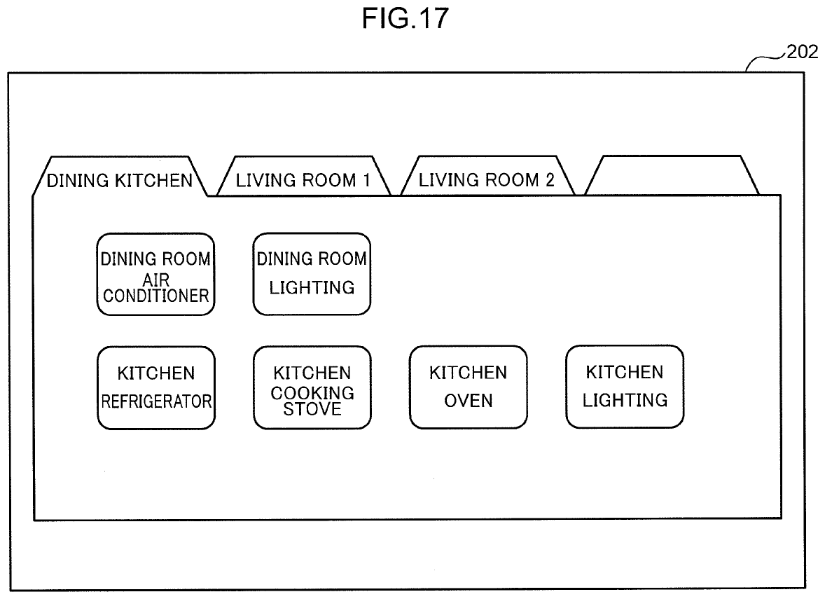

FIG. 17 is a diagram illustrating an example of the operation screen displayed on the display 202. Hereinafter, an example of the operation screen for the new second space called a dining kitchen and generated by integrating the dining room 12 and the kitchen 11 will be described. The example illustrated in FIGS. 8 and 17 shows that the new second space called a dining kitchen is provided with an air conditioner and lighting of the dining room 12, and a refrigerator, a stove, an oven, and lighting of the kitchen 11, as the control targets of the apparatuses 300 and the facilities 350.

With reference to FIG. 17, icons for individually controlling the control targets of the apparatuses 300 and the facilities 350 are displayed side by side on the display tab with a tab name of “dining kitchen”. A user can control on or off of power of the corresponding apparatuses 300 and facilities 350 by touching the icons.

The present modification enables improvement in convenience of the user because the user can control the apparatuses 300 and the facilities 350 in units of the second space with the integrated controller 200 (control device).

(Third Modification)

The space generator 503 may inquire of the user whether to reflect a grouping result instead of automatically reflecting the grouping result.

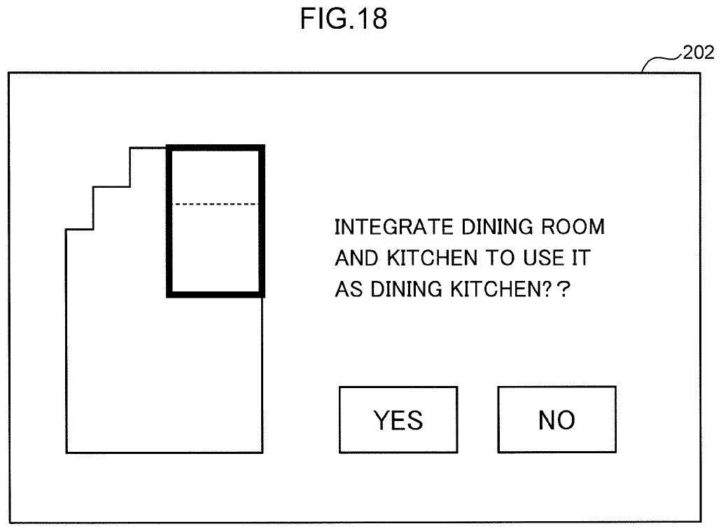

FIG. 18 is a diagram illustrating an example of an inquiry screen to the user in a simplified manner. When the space generator 503 tries to generate a new second space by integrating the dining room 12 and the kitchen 11, an inquiry screen for inquiring the user whether to permit the integration is displayed on the display 202 of the integrated controller 200. With this configuration, an intention of the user of whether to permit the integration can be checked.

### INDUSTRIAL APPLICABILITY

The present disclosure is particularly useful for application to a home control system including a smart home to which IoT technology is introduced.

1. A method for generating a space, the method comprising:
by an information processor,
acquiring room layout information on a building with multiple first spaces;
acquiring installation information on at least one of an apparatus and a facility that are installed in each first space of the multiple first spaces;
setting a use application for each of the first spaces based on the room layout information and the installation information;
defining at least one second space by grouping the multiple first spaces including at least one of integration of two or more first spaces and division of one first space based on the use application; and
outputting a result of the grouping.

2. The method for generating a space according to claim 1, further comprising:
by the information processor,
acquiring user information associating the respective first spaces with corresponding users, and
setting the use application based on the room layout information, the installation information, and the user information.

3. The method for generating a space according to claim 1, further comprising:
by the information processor,
generating relationship information indicating a correspondence relationship between the second space and at least one of the apparatus and the facility installed in the second space, and
outputting the relationship information to a control device that controls the apparatus and the facility via a communication network.

4. The method for generating a space according to claim 1, further comprising:
by the information processor, performing the grouping in accordance with a type of the use application of each of the first spaces.

5. The method for generating a space according to claim 4, further comprising:
by the information processor, setting a type of the use application of each of the first spaces based on setting information in which a type of use application of each of the apparatus and the facility is set.

6. The method for generating a space according to claim 1, wherein
the at least one second space includes multiple second spaces, and
the method further comprises, by the information processor, performing adjustment for further dividing the second space when a total number of control targets of the apparatus and the facility and installed in each second space of the multiple second spaces is equal to or larger than a first threshold as a result of the grouping.

7. The method for generating a space according to claim 1, wherein
the at least one second space includes multiple second spaces, and
the method further comprises, by the information processor, performing adjustment for integrating two or more second spaces when a total number of the multiple second spaces is equal to or larger than a second threshold as a result of the grouping.

8. An information processor comprising:
an acquisition unit that acquires room layout information on a building with multiple first spaces and installation information on at least one of an apparatus and a facility that are installed in each first space of the multiple first spaces;
an application setting unit that sets a use application for each of the first spaces based on the room layout information and the installation information that are acquired by the acquisition unit;
a space generator that defines at least one second space by grouping the multiple first spaces including at least one of integration of two or more first spaces and division of one first space based on the use application set by the application setting unit; and
an output unit that outputs a result of the grouping performed by the space generator.

9. A computer-readable recording medium recording a program for causing an information processor to function as:
an acquisition means that acquires room layout information on a building with multiple first spaces and installation information on at least one of an apparatus and a facility that are installed in each first space of the multiple first spaces;
an application setting means that sets a use application for each of the first spaces based on the room layout information and the installation information that are acquired by the acquisition means;
a space generation means that defines at least one second space by grouping the multiple first spaces including at least one of integration of two or more first spaces and division of one first space based on the use application set by the application setting means; and
an output means that outputs a result of the grouping performed by the space generation means.
